(19) United States
(12) Patent Application Publication
(10) Pub. No.: US 2024/0081063 A1
(43) Pub. Date: Mar. 7, 2024

(54) MEMORY DEVICES HAVING IMPROVED MEMORY STATE RETENTION

(71) Applicant: Applied Materials, Inc., Santa Clara, CA (US)

(72) Inventors: Milan PESIC, Paoli, PA (US); Pradeep K. SUBRAHMANYAN, Santa Clara, CA (US)

(21) Appl. No.: 18/447,457

(22) Filed: Aug. 10, 2023

Related U.S. Application Data
(60) Provisional application No. 63/403,273, filed on Sep. 1, 2022.
(60) Provisional application No. 63/436,835, filed on Jan. 3, 2023.

(51) Int. Cl. H10B 43/27; H10B 43/30

(52) U.S. Cl. CPC H10B 43/27; H10B 43/30

(57) ABSTRACT

Embodiments of the disclosure include an apparatus and method of forming an improved memory device. In some embodiments, the apparatus generally includes, for example, a plurality of alternating layers formed over a surface of a substrate including a plurality of word line layers with gate regions and a plurality of inter-word line dielectric layers; a channel; and an ONO layer stack disposed between the gate regions and the channel. The embodiments of the present disclosure may include at least one of: word line layers with gate regions that have sidewalls that have a reverse dome shape, sacrificial layers disposed between the word line layers and the inter-word line dielectric layers, or top and bottom dielectric layers deposited on top and bottom portions of the word line layers. Embodiments of the disclosure described herein may allow for the electric field of the gate regions of a memory device to be modified.

### CROSS-REFERENCE TO RELATED APPLICATION(S)

This application claims the benefit of and priority to U.S. Provisional Application 63/436,835 filed on Jan. 3, 2023, and U.S. Provisional Application 63/403,273 filed on Sep. 1, 2022, which are both hereby incorporated by reference herein in their entireties.

### BACKGROUND

### Field

The present disclosure generally relates to memory devices, and methods of manufacturing the same, and more particularly, to device structures and methods of forming three-dimensional (3D) memory devices.

### Description of the Related Art

Memory devices are an essential component in digital electronic devices that are being developed today. With the increase in technology today, there is a need for increased memory capacity in most electronic devices. At the same time there is also a need for smaller memory devices to meet the market place's desire to create smaller electronic devices in which the memory device is positioned within.

In recent years, conventional (2D) NAND memory devices have run into a number of retention loss and overall reliability challenges, including voltage drop related issues (e.g., running out of electrons in the current carrying elements due to the ever scaling of the cell size) and increased resistance due to the increasing length of channels. To address challenges encountered in scaling planar (2D) NAND memory devices to achieve higher densities at a lower cost per bit, ultra-high density, three-dimensional (3D) stacked memory structures have been introduced. Such 3D memory structures are sometimes referred to as having a Bit Cost Scalable (BiCS) architecture, and include strings of vertically integrated memory cells. Typically, the vertically aligned memory cells are formed from an array of alternating conductor and insulator layers, where the conductive layers correspond to the word lines of the memory structure.

As the number of vertically stacked memory cells in 3D NAND devices increases (e.g., as chip densities increase), the resistivity of the memory cell string (e.g., channel structure) also increases, introducing numerous performance issues. As resistivity increases, more advanced circuits are required for current sensing. Typically, the memory cell string may include a number of word line layers. As the number of vertically stacked layers increase, the overall resistance of the vertically oriented channel region of the 3D NAND memory increases, leading to a drop in the amount of current that can (1) flow in the channel structure and most importantly (2) be detected at by the sense amplifier. Based on the current design rules and pitches, as well as the current materials used, at around 500 stacked word line layers, it may not be possible to detect any current flowing through the channel region which corresponds to the stored state. In turn, the difference between stored states would be indistinguishable.

In addition, lateral charge migration (and retention loss mechanisms) between adjacent cells creates crosstalk between these cells, which poses a challenge to the implementation of 3D NAND memory devices and a limitation on the spacing between and density of stacked 3D NAND devices. Currently, it is common to utilize—larger pitch sizes to increase distance between the neighboring cells and minimize the effect of charge migration between adjacent cells. In addition to the large pitch size, two other concepts such as full-charge trap cut and partial charge trap cut concepts are investigated. However, the partial charge trap integration scheme contributes to a number of problems, including an undesirable electric field distribution and large corner electric fields in the gate region of the NAND device and its resulting effects on the operation and reliability of 3D NAND memory devices.

Therefore, there is a need for an improved memory device structure and method of forming the same that solves the problems described above.

### SUMMARY

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

Embodiments of the disclosure may provide a three-dimensional memory device. The three-dimensional memory device generally includes a plurality of alternating layers formed over a surface of a substrate, wherein the plurality of alternating layers comprise a word line layer and an inter-word line dielectric layer that are sequentially stacked in a first direction, wherein the word line layer has a gate region that has a sidewall that has a reverse dome shape. The three-dimensional memory device also generally includes a channel having a first end coupled to a source line, a second end coupled to a drain line, and extending in the first direction between the source line and the drain line; and an ONO layer stack disposed between the gate region and the channel, wherein the ONO layer stack extends in the first direction between the source line and the drain line. The ONO layer stack generally includes a first oxide layer which conforms to the reverse dome shape of the sidewall, and a first silicon nitride layer with at least one portion that substantially fills a space formed between the reverse dome shape of the first oxide layer and a surface of the channel.

Embodiments of the disclosure may provide a method of forming a three-dimensional memory device. The method of forming a three-dimensional memory device generally includes forming a plurality of alternating layers over a surface of a substrate, comprising forming a plurality of dummy nitride layers and a plurality of inter-word line dielectric layers that are sequentially stacked in a first direction over a source line layer that is disposed over the surface of the substrate, and etching a plurality of openings extending in the first direction from the source line layer and through the plurality of alternating layers. The method of forming a three-dimensional memory device also generally includes selectively forming a recess in a surface of each of the plurality of dummy nitride layers that are exposed within each of the formed plurality of openings, wherein the selectively formed recesses each have reverse dome shape, and forming a channel region within the plurality of openings. Forming the channel region generally includes depositing an ONO layer stack over the surface of each of the plurality of openings, which includes forming a first oxide layer which conforms to the reverse dome shape of a sidewall of the dummy nitride layer, and forming a first silicon nitride layer that substantially fills a space between the reverse dome shape of the first oxide layer and a surface of the channel region. Forming the channel region generally also includes forming a channel over a surface of the ONO layer stack, forming an oxide over a surface of the channel. The method of forming a three-dimensional memory device generally also includes removing the dummy nitride layer, forming a word line layer in place of the removed dummy nitride layer and over the ONO stack, wherein the word line layer has a gate region that has a sidewall that has a reverse dome shape, and forming a drain line layer over the plurality of alternating layers, wherein at least a portion of the channel region formed within each of the plurality of openings are coupled to a portion of the drain line layer and a portion of the source line layer.

Embodiments of the disclosure may provide a three-dimensional memory device. The three-dimensional memory device generally includes a plurality of alternating layers formed over a surface of a substrate, wherein the alternating layers comprises a word line layer, an inter-word line dielectric layer, and a sacrificial layer disposed between the word line layer and the inter-word line dielectric layer, wherein the plurality of alternating layers are stacked in a first direction, and the word line layer has a gate region. The three-dimensional memory device also generally includes a channel having a first end coupled to a source line, a second end coupled to a drain line, and extending in the first direction between the source line and the drain line, and an ONO layer stack disposed between the gate region and the channel, wherein the ONO layer stack extends in the first direction between the source line and the drain line. The ONO layer stack generally includes a first oxide layer, and a first silicon nitride deposited over the first oxide layer.

Embodiments of the disclosure may provide a method of forming a three-dimensional memory device. The method of forming a three-dimensional memory device generally includes forming a plurality of alternating layers over a surface of a substrate, comprising forming a plurality of dummy nitride layers, a plurality of inter-word line dielectric layers, and a plurality of sacrificial layers that are sequentially stacked in a first direction over a source line layer that is disposed over the surface of the substrate, wherein each of the plurality of sacrificial layers are disposed between one of the plurality of dummy nitride layers and one of the plurality of inter-word line dielectric layers. The method of forming a three-dimensional memory device generally also includes etching a plurality of openings extending in the first direction from the source line layer and through the plurality of alternating layers, and forming a channel region within the plurality of openings. Forming the channel region generally includes depositing an ONO layer stack over the surface of each of the plurality of openings, which includes forming a first oxide layer; and a first silicon nitride deposited over the first oxide layer. Forming the channel region generally also includes forming a channel over a surface of the ONO layer stack, and forming an oxide over a surface of the channel. The method of forming a three-dimensional memory device generally also includes removing the dummy nitride layer, forming a word line layer in place of the removed dummy nitride layer and over the ONO stack, wherein the word line layer has a gate region, and forming a drain line layer over the plurality of alternating layers, wherein at least a portion of the channel region formed within each of the plurality of openings are coupled to a portion of the drain line layer and a portion of the source line layer.

Embodiments of the disclosure may provide a three-dimensional memory device. The three-dimensional memory device generally includes a plurality of alternating layers formed over a surface of a substrate, wherein the alternating layers comprise: a word line layer and an inter-word line dielectric layer that are stacked in a first direction, wherein the word line layer has a gate region, a top dielectric layer deposited on a top portion of the word line layer, and a bottom dielectric layer deposited on a bottom portion of the word line layer, wherein the top dielectric layer and the bottom dielectric layer are both in a second direction and are configured to change an electric field at opposing edges of the gate region. The three-dimensional memory device also generally includes a channel having a first end coupled to a source line, a second end coupled to a drain line, and extending in the first direction between the source line and the drain line, and an ONO layer stack disposed between the gate region and the channel, wherein the ONO layer stack extends in the first direction between the source line and the drain line. The ONO layer stack generally includes a first oxide layer, and a first silicon nitride deposited over the first oxide layer.

Embodiments of the disclosure may provide a method of forming a three-dimensional memory device. The method of forming a three-dimensional memory device generally includes forming a plurality of alternating layers over a surface of a substrate, comprising: forming a plurality of dummy nitride layers and a plurality of inter-word line dielectric layers that are sequentially stacked in a first direction over a source line layer that is disposed over the surface of the substrate, forming a plurality of top dielectric layers each deposited on a top portion of each of the plurality of dummy nitride layers, and forming a plurality of bottom dielectric layers each deposited on a bottom portion of each dummy nitride layer, wherein the plurality of top dielectric layers and the plurality of bottom dielectric layers are both in a second direction. The method of forming a three-dimensional memory device also generally includes etching a plurality of openings extending in the first direction from the source line layer and through the plurality of alternating layers, and forming a channel region within the plurality of openings. Forming the channel region generally includes depositing an ONO layer stack over the surface of each of the plurality of openings, which includes forming a first oxide layer, and forming a first silicon nitride deposited over the first oxide layer. Forming the channel region generally also includes forming a channel over a surface of the ONO layer stack, and forming an oxide over a surface of the channel. The method of forming a three-dimensional memory device generally also includes removing the dummy nitride layer, forming a word line layer in place of the removed dummy nitride layer and over the ONO stack, wherein the word line layer has a gate region, and wherein the plurality of top dielectric layers and the plurality of bottom dielectric layers are configured to change an electric field at opposing edges of the gate region, and forming a drain line layer over the plurality of alternating layers, wherein at least a portion of the channel region formed within each of the plurality of openings are coupled to a portion of the drain line layer and a portion of the source line layer.

Embodiments of the disclosure may provide a three-dimensional memory device. The three-dimensional memory device generally includes a plurality of alternating layers formed over a surface of a substrate, wherein the plurality of alternating layers comprise word line layers and inter-word line dielectric layers that are sequentially stacked in a first direction, wherein each of the word line layers has a gate region that has a sidewall that has a reverse dome shape. The three-dimensional memory device also generally includes a channel having a first end coupled to a source line, a second end coupled to a drain line, and extending in the first direction between the source line and the drain line, and an ONO layer stack disposed between the gate regions and the channel, wherein the ONO layer stack extends in the first direction between the source line and the drain line.

Embodiments of the disclosure may provide a three-dimensional memory device. The three-dimensional memory device generally includes a plurality of alternating layers formed over a surface of a substrate, wherein the plurality of alternating layers comprise word line layers and inter-word line dielectric layers that are sequentially stacked in a first direction, wherein each of the word line layers has a gate region that has a sidewall that has a reverse dome shape. The three-dimensional memory device also generally includes a channel having a first end coupled to a source line, a second end coupled to a drain line, and extending in the first direction between the source line and the drain line; and an ONO layer stack disposed between the gate regions and the channel. The ONO layer stack may include a first oxide layer, a first silicon nitride layer and a second oxide layer and may extend in the first direction between the source line and the drain line, and wherein the first oxide layer conforms to the reverse dome shape of the sidewall, the first silicon nitride layer is disposed between the first oxide layer and the second oxide layer, the first silicon nitride layer has a first portion that substantially fills a space formed in the gate regions between the reverse dome shape of the first oxide layer and a surface of the second oxide layer, the first silicon nitride layer has a plurality of second portions that are disposed over each of the inter-word line dielectric layers and between gate regions, and a thickness of the first silicon nitride layer in a first direction is less over a surface of the inter-word line dielectric layers than a thickness of the first silicon nitride layer in the first direction over the gate regions of the word line layers.

Embodiments of the disclosure may provide a method of forming a three-dimensional memory device. The method of forming a three-dimensional memory device generally includes forming a plurality of alternating layers over a surface of a substrate, comprising: forming a plurality of dummy nitride layers and a plurality of inter-word line dielectric layers that are sequentially stacked in a first direction over a source line layer that is disposed over the surface of the substrate, and etching a plurality of openings extending in the first direction from the source line layer and through the plurality of alternating layers. The method of forming a three-dimensional memory device generally also includes selectively forming a recess in a surface of each of the plurality of dummy nitride layers that are exposed within each of the formed plurality of openings, wherein the selectively formed recesses each have reverse dome shape, and forming a channel region within the plurality of openings. The formation of the channel region generally includes depositing an ONO layer stack over the surface of each of the plurality of openings, and forming a channel over a surface of the ONO layer stack. The method of forming a three-dimensional memory device generally also includes removing the dummy nitride layer, forming a word line layer in place of the removed dummy nitride layer and over the ONO stack, wherein the word line layer has a gate region that has a sidewall that has a reverse dome shape; and forming a drain line layer over the plurality of alternating layers, wherein at least a portion of the channel region formed within each of the plurality of openings are coupled to a portion of the drain line layer and a portion of the source line layer.

In some embodiments of the disclosure, the method of forming a three-dimensional memory device may include an ONO layer stack that extends in the first direction between the source line and the drain line. The method of forming a three-dimensional memory device may also include depositing the ONO layer stack over the surface of each of the plurality of openings may include depositing a first oxide layer which conforms to the reverse dome shape of the sidewall, depositing a first silicon nitride layer over the first oxide layer, wherein the first silicon nitride layer conforms to the reverse dome shape of the first oxide layer, and a thickness of the first silicon nitride layer is greater over a surface of the inter-word line dielectric layers than a thickness of the first silicon nitride layer in the first direction over the gate region of the word line layer. The method of forming a three-dimensional memory device may also include etching the first silicon nitride layer to minimize the thickness of the first silicon nitride layer over the surface of the inter-word line dielectric layers.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a simplified schematic example of a 3D NAND memory structure.

FIG. 2 illustrates an example of a portion of a channel layer structure and stacked layer pairs that each include a dielectric layer and a word line layer formed within a 3D NAND memory structure.

FIG. 3A is a schematic diagram of a conventional 3D NAND memory structure.

FIGS. 3B and 3D illustrate an example of lateral charge migration created in a portion of the conventional 3D NAND memory structure illustrated in FIG. 3A.

FIG. 3C is plot illustrating an electric field created between memory cells by the presence of the lateral charge stored in the center memory cell within the 3D NAND memory structure illustrated in FIG. 3B.

FIG. 4 illustrates a method for use in the manufacturing of a memory cell gate stack portion of a semiconductor device, such as forming a portion of the 3D NAND memory structure, according to one or more of the embodiments described herein.

FIGS. 5A, 5B, 5C, 5D, 5E, 5F, and 5G illustrate schematic side cross-sectional views of a portion of a 3D NAND memory structure during formation, according to one or more of the embodiments described herein.

FIG. 6 illustrates a method for use in the manufacturing of a memory cell gate stack portion of a semiconductor device, such as forming a portion of the 3D NAND memory structure, according to one or more of the embodiments described herein.

FIGS. 7A, 7B, 7C, 7D, 7E, 7F, and 7G illustrate schematic side cross-sectional views of a portion of a 3D NAND memory structure during formation, according to one or more of the embodiments described herein.

FIG. 8 illustrates a method for use in the manufacturing of a memory cell gate stack portion of a semiconductor device, such as forming a portion of the 3D NAND memory structure, according to one or more of the embodiments described herein.

FIGS. 9A, 9B, and 9C illustrate schematic side cross-sectional views of a portion of a 3D NAND memory structure during formation, according to one or more of the embodiments described herein.

FIGS. 10A, 10B, and 10C provide diagrams illustrating a 3D NAND memory structure 100 with an improved partial charge trap integration, according to one or more of the embodiments described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

In the following description, details are set forth by way of example to facilitate an understanding of the disclosed subject matter. It should be apparent to a person of ordinary skill in the field, however, that the disclosed implementations are exemplary and not exhaustive of all possible implementations. Thus, it should be understood that reference to the described examples is not intended to limit the scope of the disclosure. Any alterations and further modifications to the described devices, instruments, methods, and any further application of the principles of the present disclosure are fully contemplated as would normally occur to one skilled in the art to which the disclosure relates. In particular, it is fully contemplated that the features, components, and/or steps described with respect to one implementation may be combined with the features, components, and/or steps described with respect to other implementations of the present disclosure. As used herein, the term “about” may refer to a +/−10% variation from the nominal value. It is to be understood that such a variation can be included in any value provided herein.

Embodiments of the disclosure provided herein include an apparatus for and method of forming an improved three-dimension (3D) memory structure that includes a partial charge-trap structure that improves memory retention. In some embodiments, after memory hole patterning, a dielectric layer within a multilayer stack can be slightly recessed to allow the formation of a gate structure that will attenuate corner electric field(s) originating from the gate region of the NAND device during operation. In some embodiments, before the barrier metal and word line fill processes are performed to create the word lines within the NAND device, top and bottom shielding dielectrics can be deposited on or over the dummy nitride layers within the ONO stack within the 3D NAND device to attenuate the high electric field(s) at corners originating from the gate region of the NAND device during operation. In some embodiments, an additional sacrificial layer may be added to the standard oxide and dummy nitride layer to mitigate the corner electric field originating from the gate region of the NAND device during operation. In some embodiments, the position of the word line layer may be offset in order to modify the electric field of the gate regions of a memory device.

Embodiments of the disclosure may provide a method of forming 3D NAND memory devices, which will mitigate the undesirable electric field effects caused by conventional partial charge trap integration designs. In this manner, the memory devices may benefit from improved reliability and improved retention.

Embodiments disclosed herein can be useful for, but are not limited to, channel structures in two dimensional (2D) and 3D memory devices.

### Example 3D NAND Memory Structure

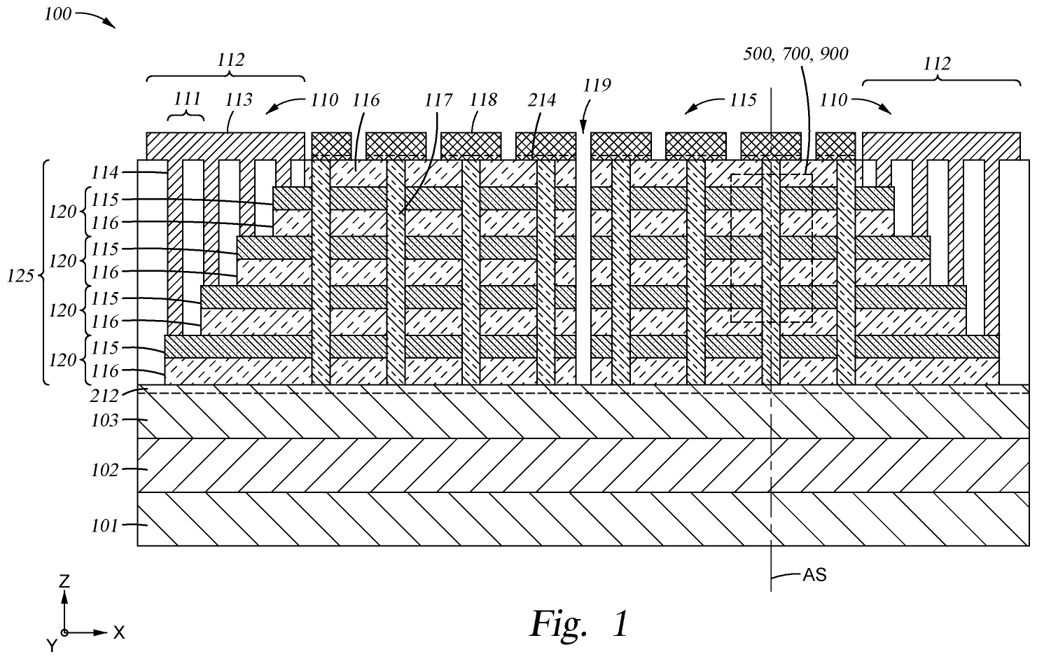

FIG. 1 is a simplified schematic example of a 3D NAND memory structure 100. The 3D NAND memory structure includes a channel structure 117 that is oriented in a vertical direction, such that the channel structure 117 is oriented perpendicular (e.g., −Z-direction) to a major surface of the substrate 101 that includes an etch stop layer (ESL) 102 and a common source line layer (CSL) 103 disposed thereon. The top of the vertical channel structure 117 includes a plurality of bit lines 118. The stacked layers are configured in stacked layer pairs 120 that each include a dielectric layer 116 and a word line layer 115. In this configuration, the word line layers 115 (e.g., four layers shown in FIG. 1) are stacked in the direction that is perpendicular to the major surface of the substrate to form a string of memory cells and each include a portion of one of the channel structures 117. At an end of each word line layer 115 is a staircase-like structure 110. In the staircase-like structure 110, one or more conductive columns 114 are used to connect the word line layer 115 to an external control circuit by use of connecting element lines 113. In this way, in the 3D NAND memory structure 100, a memory cell may be fabricated in a vertical direction, so that a memory capacity may be easily increased by stacking additional layers. A gate slit line 119 may also be formed through the 3D NAND memory structure 100. It should be noted that, in some embodiments, the word line layer 115 is deposited later in the process of forming the 3D NAND device by removing a dummy (second) dielectric material (e.g., dummy nitride material) by use of an etching process and then depositing a conductive layer in same place where the dummy (second) dielectric material was positioned.

The 3D NAND memory structure 100 may also include a source region 212 (e.g., N+ source layer), which may be part of or formed on the CSL 103, and a drain region 214 (e.g., N+ drain layer), which may be part of or formed under the plurality of bit lines 118. The staircase-like structures 110, which are formed on two opposing edges of the 3D NAND memory structure 100, require a two-dimensional area (i.e., X-Z plane) to connect all of the word line layers 115 to external elements outside of the 3D NAND device.

### Lateral Charge Migration in Memory Devices

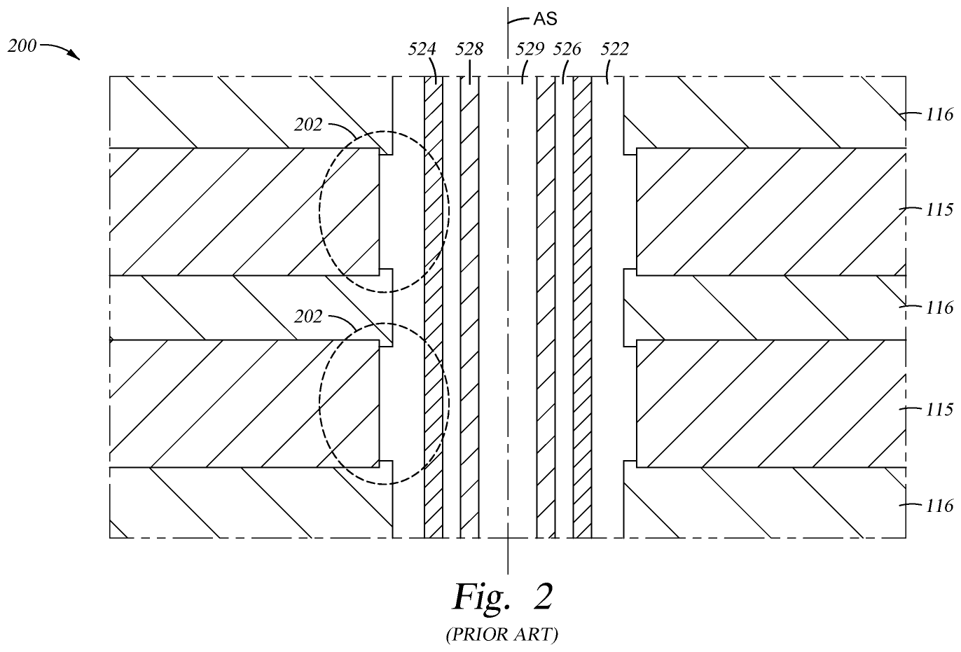

FIG. 2 illustrates an example of a portion 200 of a channel structure 117 (FIG. 1) and stacked layer pairs 120 that each include a dielectric layer 116 and a word line layer 115 formed within a 3D NAND memory structure 100. The channel structure 117 includes a one or more dielectric layers (blocking oxide) 522, a silicon nitride layer (charge trap layer) 524, a one more (or multiple) dielectric layers (tunnel oxide) 526, a channel layer 528, and a filler layer 529. Some embodiments can comprise SiO₂/SiN/SiO₂ tunnel oxide, SiN charge trap nitride, SiO₂ blocking oxide and Al₂O₃ high-k barrier layer. The portion 200 of a channel structure 117 and stacked layer pairs 120 may be symmetrical across the axis of symmetry (AS). In the current disclosure, these blocks may be referred to as a dielectric layer/nitride layer/second dielectric layer or ONO layer stack. In some embodiments, and as shown in FIG. 2, the 3D NAND memory structure 100 may have gate regions that include a rectangular step or flat shaped gate structure (e.g., 202), as described above.

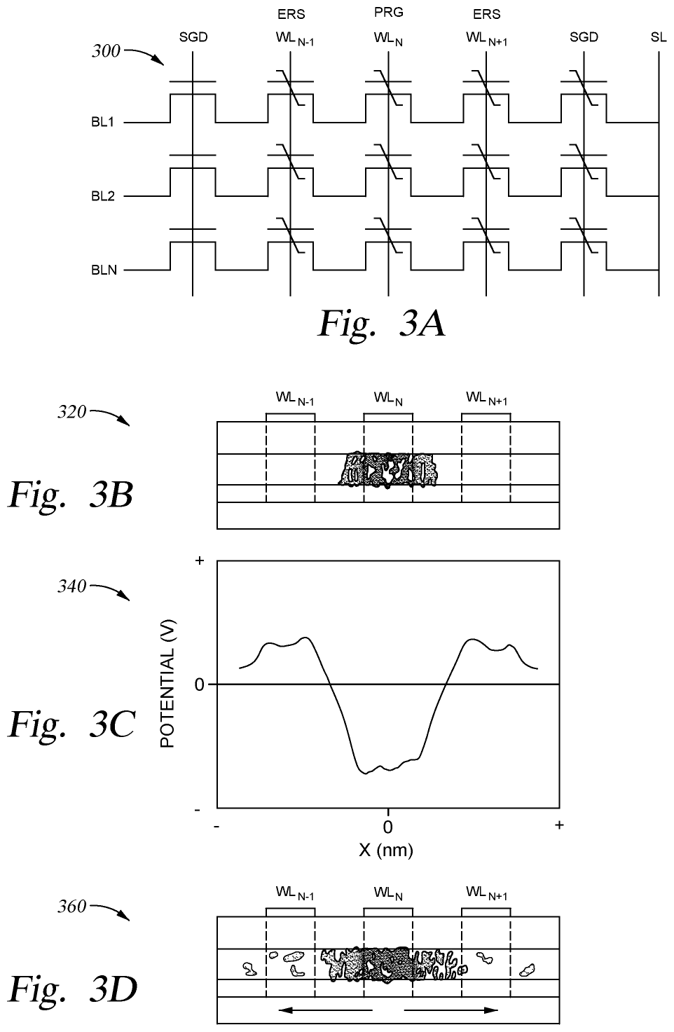

FIGS. 3B and 3D illustrate an example of lateral charge migration created in a portion of a conventional 3D NAND memory structure. FIG. 3C is plot illustrating an electric field created between memory cells by the presence of the lateral charge stored in the center memory cell within the 3D NAND memory structure illustrated in FIG. 3B. In some embodiments, the 3D NAND memory structure may be a BiCS 3D NAND memory structure. In certain configurations of 3D NAND memory structures (e.g., 3D NAND memory structure 100), lateral charge migration and the corresponding cell-to-cell crosstalk can cause memory retention issues. Configurations of the 3D NAND memory structure 100 may include N-P-N and E-P-E arrays (e.g., E-P-E array 300). In following, we will explain the E-P-E configuration as the most problematic case for the retention of the 3D NAND array. In this configuration, block erase (E) is followed by the program (P) where the programmed cell is in between two previously erased cells. In parts of the present disclosure, we will target and program the word line N, WL_{N}. When a block erase is performed, the entirety of the memory device block is erased. In order to perform a block erase, an erase program erase constellation is formed. High positive voltages are applied and source and drain line which erase all the cells from top to the bottom of the channel. All charge trapping nitrides are emptied of electrons. After block erase of the 3D NAND memory structure 100, program is applied to the center of the array (e.g., WL_{N}). During the program operation, charge carriers are injected into the charge trapping nitride of the WL_{N}. As a result the programed WL_{N} have charge, while the neighboring cells (e.g., WL_{N-1}, WL_{N+1}) on either side of the center of the array to have no stored charge. As a result, an internal electric field is created in the array 300, as illustrated by the potential versus lateral distance curve shown in FIG. 3C. An example of the consequence of this internal electric field can be seen in by the initially stored charge diagram 320 and corresponding curve 340 (FIGS. 3B and 3C, respectively), where initial charge distribution and final charge distribution before and after lateral charge migration are illustrated in 320 and 360, respectively (FIGS. 3B and 3D, respectively). The diagrams 320 and 360 show charge trap regions (and corresponding migrating trapped charge) of three word line layers 115 (e.g., WL_{N-1}, WL_{N}, WL_{N+1}) stacked on top of each other, but presented in a horizontal arrangement in FIGS. 3B and 3D. In one example, the initially stored charge, which is illustrated in the initially stored charge diagram 320, is predominantly in the charge trap region of the middle word line (e.g., WL_{N}) due to the step of programming a charge in this memory location. In other words, each cell which has a charge on it (e.g., WL_{N}) will have high potential, and the cells without any charge (e.g., WL_{N-1}, WL_{N-2}) will have low potential, as shown in example in diagram 320 and corresponding curve 340. The internal electric field is shown in the center word line layer 115 (e.g., WL_{N}) in example 320 and corresponding curve 340, which depicts the stored charge at the moment when the center word line layer 115 is programmed. As shown, a large portion of the stored charge is centralized adjacent to the gate positioned at the WL_{N}. Diagram 360 illustrates the same charge trap regions (and corresponding previously trapped charge) of the three word line layers 115 after a period of time has elapsed and shows the effect of the generated internal electric field on the stored charge found in center word line layer 115 (e.g., WL_{N}) on the charge stored in the adjacent to the charge trap regions WL_{N-1} and WL_{N+1}. As a consequence of the internal electric field, the stored charge will tend to migrate, laterally, to the adjacent cells (e.g., WL_{N-1}, WL_{N-2}).

For instance, in the example illustrated in diagram 360, the middle word line (e.g., WL_{N}) electric field may drive the stored charge to the adjacent cells (e.g., WL_{N-1}, WL_{N-2}) within the charge trap region of the channel structure 117 over time. Diagram 360 shows the word line layers 115 of diagram 320 after a period of time (e.g., hours) has elapsed. In diagram 360, we can see that the stored charge has migrated laterally (i.e., as shown in FIG. 3D), creating a redistribution of the trapped charge due to the lateral charge migration created by the internal electric field. As shown, the charge migration moves from a region of high charge concentration at the center cell, which includes word line WL_{N}, to a region of lower charge concentration in the top or bottom cells, which include word lines WLₙ₋₁ and WLₙ₊₁, respectively. Therefore, as time passes, the amount of charge in the central cell diminishes and the other cells receive an amount of charge. The charge migration causes cell-to-cell cross talk and disturbs the memory state of the neighboring cells, and often results in memory retention and memory state fidelity issues for the 3D NAND memory structure 100.

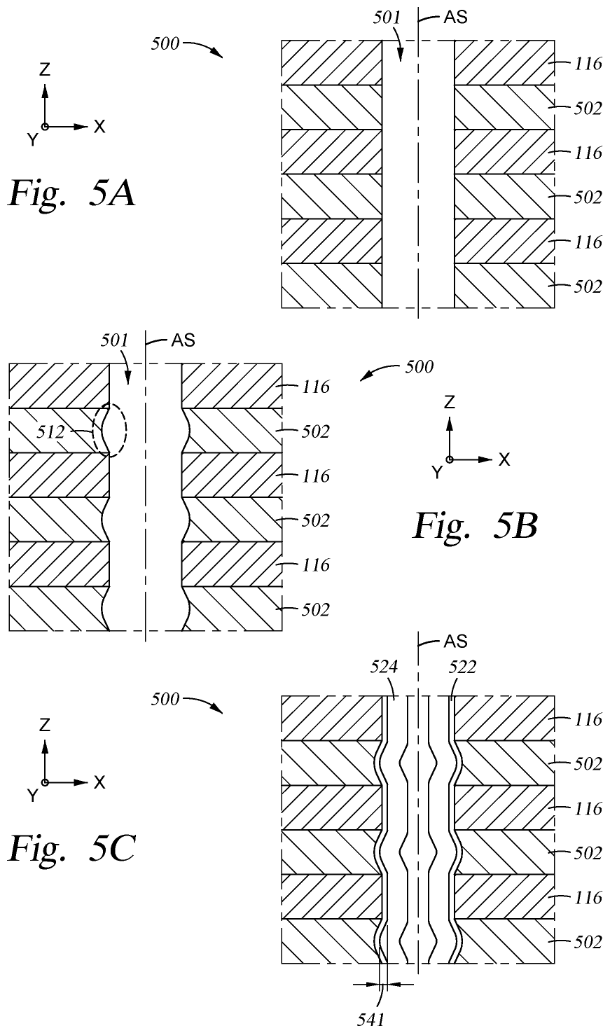

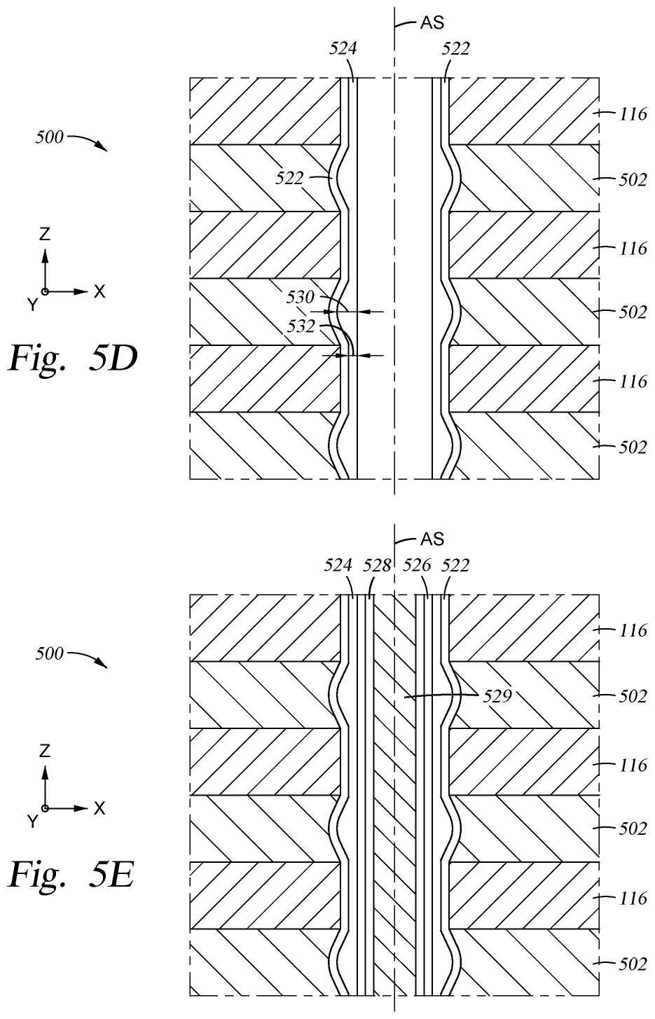

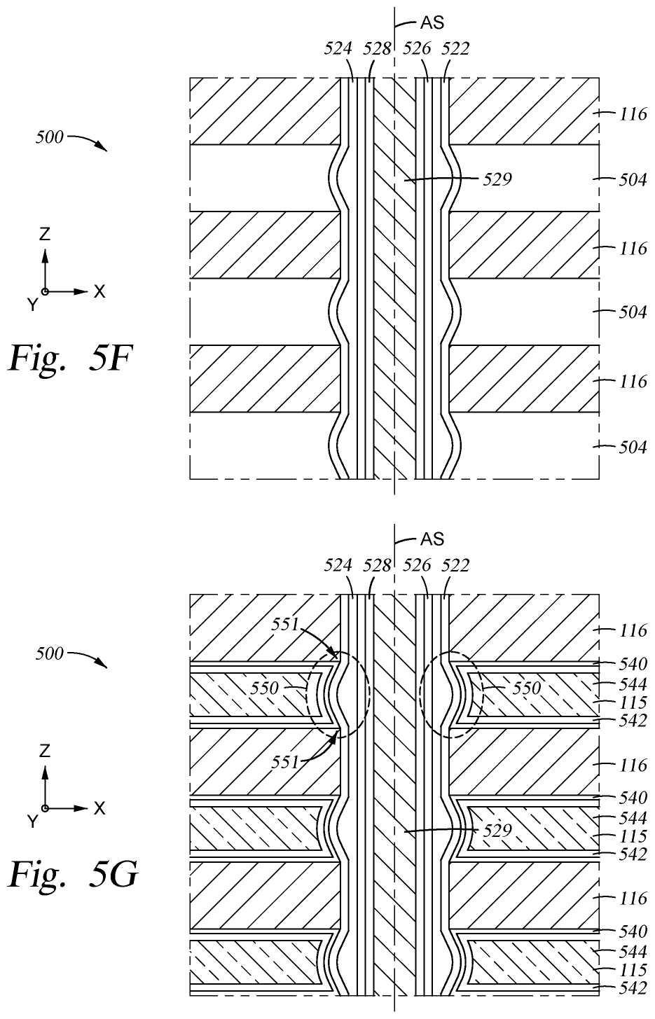

In some embodiments of the 3D NAND structure disclosed herein, and as shown below in FIG. 5D, the thickness of the first oxide layer 522 adjacent to the gate region (thickness 530) is thicker than the thickness of the first oxide layer 522 adjacent to the dielectric layer 116 (thickness 532). As a result, charge migration between adjacent memory cells is mitigated due to the thinner first oxide layer 522 thickness disposed between adjacent memory cells that tends to constrict the flow of charge (e.g., creates a higher electrical resistance) to adjacent memory cells. In other words, the high density charge illustrated in FIG. 3B remains largely trapped in the portion of the charge trap layer 524 positioned over the middle word line (e.g., WL_{N}), and there is a lower probability that the high density charge in the charge trap layer 524 will migrate to the adjacent memory cells.

Accordingly, embodiments of the present disclosure provide an improved memory device that may mitigate lateral charge migration.

### Example 3D NAND Memory Formation and Structure with Improved Partial Charge Trap Integration

Due to the layered structure of 3D NAND devices it is common for the gate region of a cell to include a rectangular step or flat shaped gate structure (e.g., 202) due to the ease with which these types of structures are manufactured, as illustrated in FIG. 2. As a consequence of the formed flat or step shaped structure, discontinuities and deviations in the electric field are formed at the edges of the step shaped structure that forms part of the gate region of memory device during operation. As a result, many conventional integration schemes result in a parasitic or imperfectly shaped gate regions, which may cause large electric fields to form at the edges and corners of the step shaped structure. It is believed that at the edges of the step shaped structure, a much higher electric field (e.g., 20% higher electric field compared to the center of the dome structure) is created. As a result, a 20% or higher electric field can be formed over the tunneling oxide (FIG. 2), and thus the reliability of the memory cell can be compromised, due to higher density of stored charge collecting in the high electric field regions at the edges of the gate region that are at the edges of the memory device, and dielectric breakdown may occur, which affects the ability of a 3D NAND cell to retain charge within the charge trap region. The collection of charge at the edge of the memory device also makes it more likely that the higher density of charge found in these regions will migrate to adjacent memory cells.

### 3D NAND Device Formation and Structure Sequence One

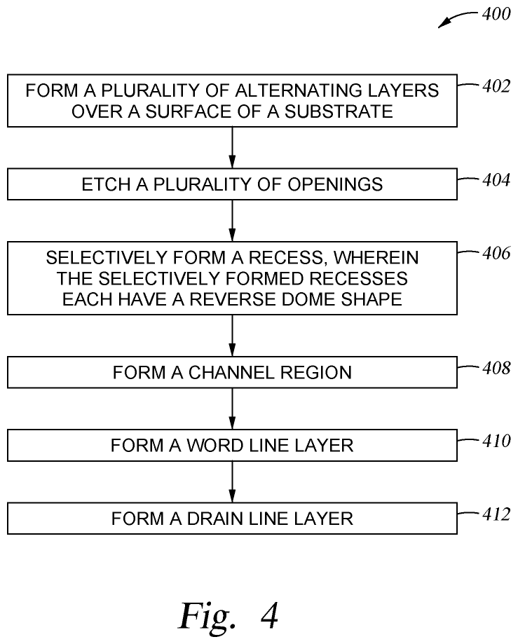

FIG. 4 illustrates a method 400 for use in the manufacturing of a memory cell gate stack portion of a semiconductor device, such as forming a portion 500 of the 3D NAND memory structure 100, according to one or more of the embodiments described herein. FIGS. 5A, 5B, 5C, 5D, 5E, 5F, and 5G illustrate schematic side cross-sectional views of portions (e.g., 500) of the 3D NAND memory structure 100 during one or more of the activities illustrated in FIG. 4, according to one or more of the embodiments described herein. Therefore, FIG. 4 and FIGS. 5A, 5B, 5C, 5D, 5E, 5F, and 5G are herein described together for clarity. It is assumed that the plurality of alternating layers 125 were previously deposited and that memory holes are opened by high aspect ratio etching. The portion 500 of the 3D NAND memory structure 100 may be symmetrical across the axis of symmetry (AS).

The method 400 begins at activity 402, where a plurality of alternating layers 125 are formed over a surface of a substrate 101. In some embodiments, forming the plurality of alternating layers 125 may include forming a plurality of dummy nitride layers 502 and a plurality of inter-word line dielectric layers 116 that are sequentially stacked in a first direction over a common source line (CSL) 103 that is disposed over the surface of the substrate 101.

At activity 404, a plurality of openings (e.g., memory holes) extending in the first direction from the CSL 103 and through the plurality of alternating layers 125 are etched, as shown in FIG. 5A. The memory holes 501 may be etched using a high aspect ratio etching process. Further, the memory holes extend from a CSL 103 (FIG. 1) through a plurality of alternating layers 125 perpendicular (e.g., −Z-direction) to a major surface of the substrate 101.

At activity 406, a recess (e.g., recess 512) is selectively formed in a surface of each of the plurality of dummy nitride layers 502 that are exposed within each of the formed memory holes 501, as shown in FIG. 5B. The formation of the recess 512 may referred to as a recessing process. In some embodiments, the selectively formed recesses may each have a reverse dome shape (e.g., recesses 512 in FIG. 5B). Embodiments of the present disclosure, including FIGS. 5A, 5B, 5C, 5D, 5E, 5F, and 5G, provide an improved integration scheme for creating a reverse dome shaped structure in the recess 512 in order to reduce the electric field formed at the edges of the gate regions (e.g., gate region 550 shown in FIG. 5G) and near the edges of the word line layer 115 (e.g., edges 551 in FIG. 5G). For example, FIG. 5B illustrates stacked layer pairs 120 of the 3D NAND memory structure 100 after a process that selectively and preferentially etches the dummy nitride material is used to purposefully form a reverse dome shape in the dummy nitride layer 502 formed within the stacked layer pairs 120 within the plurality of alternating layers 125 before the dummy nitride layer 502 is removed and the word line layer 115 is formed. The dome shape may be a half cylinder shape, a concave cylinder shape, or a half sphere shape. The dome shape may have a rounded, curving or non-linear shape instead of having a straight, flat, linear or planar surface shape. In some embodiments, the dome shape may be a reverse dome shape because the center of the curved surface portion of the dome shape may extend away from the memory hole 501 and towards the dummy nitride layer 502 (e.g., −x direction), as illustrated in FIG. 5B. The purposefully formed reverse dome shape is used to form a gate region that will have a curved shape on the word-line side of the gate region and is thus adapted to minimize the variation in the electric field near the corners of the word line layer 115, as compared to other conventional step shaped structures within a partial cut charge trap implementations In some embodiments, a SRP process available from Applied Materials Inc. of Santa Clara, California is used to form the reverse dome shape within the sidewall of the dummy nitride layers 502.

At activity 408, a channel structure 117 is formed within the memory holes. The process of forming the channel structure 117 includes depositing an ONO layer stack over the surface of each of the memory holes in a portion 500 of the 3D NAND memory structure 100 by use of an atomic layer deposition (ALD) or chemical vapor deposition (CVD) process, as shown in FIG. 5C. Depositing the ONO layer stack includes forming a first dielectric layer (e.g., first oxide layer 522) which conforms to the reverse dome shape of a sidewall of the dummy nitride layer 502. The process of depositing the first oxide layer 522 may include, for example, depositing a layer (e.g., a continuous layer) of aluminum oxide (Al₂O₃ or similar) and or silicon oxide (SiOₓ) on sides that define the plurality of openings formed in the plurality of alternating layers 125 and along the CSL 103 and/or ESL 102 at the bottom of the memory holes. The first oxide layer(s) 522 are forming so-called barrier oxide layer, which can be a silicon oxide layer or a high-k layer of the memory cell.

The process of depositing the ONO layer stack also includes depositing a first silicon nitride layer (e.g., charge trap layer 524) on the first oxide layer 522 by use of an atomic layer deposition (ALD) or chemical vapor deposition (CVD) process, as shown in FIG. 5C. The charge trap layer 524 may include a layer of trap-silicon nitride (Si₃N₄), or even a polycrystalline silicon (poly-Si) layer (floating gate NAND cell architecture).

In some embodiments, the process of forming the charge trap layer 524 utilizes a conformal deposition process, such as an ALD process that is used to deposit a charge trap layer to a thickness so that it fills the recessed region formed within gate region, as shown in FIG. 5C. In one embodiment, a thickness of the as-deposited charge trap layer 524 is equal to or greater than the distance 541 measured between the tip of the reverse dome shape at the surface of the first oxide layer 522 and the surface of the first oxide layer 522 over the inter-word line dielectric layers 116. In this case, it is desirable for the thickness of the as-deposited charge trap layer 524 to be equal to or extends above the surface of the first oxide layer 522 over the inter-word line dielectric layers 116 (i.e., X-direction) to assure that the thickness of the charge trap layer 524 fills the reverse dome region. Then, as part of activity 408, an etching process is performed within each of the channel structures 117 to selectively remove the thickness of the charge trap layer disposed over the surface of the dielectric layer 116, as shown in FIG. 5D. This etching process may minimize the thickness of the charge trap layer 524 disposed over the surface of the dielectric layer 116 within the memory hole, and minimize the cross-sectional area through which the stored charge within a memory cell can migrate between adjacent cells. The removal of portions of the as-deposited charge trap layer 524 to thin the layer thickness disposed over the inter-word line dielectric layers 116 is created by use of a dry etching process. After performing activity 408, the charge trap layer 524 is formed in at least a half cylinder shape in each of the gate regions within the plurality of alternating layers 125.

The process of depositing the ONO layer stack also includes forming a second dielectric layer (e.g., second oxide layer 526) over the charge trap layer 524 by use of an atomic layer deposition (ALD) or chemical vapor deposition (CVD) process, as shown in FIG. 5E. The second oxide layer 526 may include a layer of silicon oxide (SiOₓ) or band-gap engineered combination of the SiO₂/SiN/SiO₂. The second oxide layer 526, or the combination of band-gap engineered layers, can be used to form a tunneling oxide region of the device. The first oxide layer 522, the charge trap layer 524, and the second oxide layer 526 altogether are an example of a simplified ONO layer stack.

The process of forming the channel structure 117 also includes depositing a channel layer 528 in the plurality of openings over the second dielectric layer 526, by use of an atomic layer deposition (ALD) or chemical vapor deposition (CVD) process, as shown in FIG. 5E. In one example, the channel layer 528 may be a polysilicon layer. In another example, the channel layer 528 may be an amorphous indium zinc oxide (IZO) containing layer. In another example, the channel layer 528 may be a multi-layer channel that includes two or more layers that are formed of different materials. For example, a first part of the channel layer may be indium zinc oxide (IZO), and a second part of the channel layer may be an amorphous indium gallium zinc oxide (IGZO) containing part.

In some embodiments of the channel structure 117, a filler layer 529 is deposited in the memory holes in a portion of the 3D NAND memory structure 100 on the channel layer 528. In one example, the filler layer material may be silicon dioxide (SiO₂), aluminum oxide (Al₂O₃), or silicon nitride (Si₃N₄). In some embodiments, the deposition of the filler layer 529 may fill the remainder of the memory hole in the 3D NAND memory structure 100. The filler layer 529, such as an oxide layer, can be deposited using any suitable deposition processes and/or apparatus. For example, atomic layer deposition (ALD) or chemical vapor deposition (CVD) may be used to deposit the channel layer 528 and second channel layer, the ONO layer stack, and the filler layer 529. Alternatively or additionally, a stand-alone apparatus or a cluster tool can be used to perform an atomic layer deposition (ALD) process. Exemplary apparatus that can be configured for performing the above process include, for example, the OLYMPIA line of ALD apparatus, available from Applied Materials, Inc.

At activity 410, a word line layer 115 is formed in place of the removed dummy nitride layer 504 and over the ONO stack, as shown in FIG. 5G. However, at the start of activity 410, the dummy nitride layer 502 is removed by use of an etching process, as shown in FIG. 5F. In one example, the word line layer 115 includes three layers, a first layer 540 which is aluminum oxide (Al₂O₃), a second layer 542 which is titanium nitride (TiN), and a third layer 544 which may be molybdenum (Mo) or Tungsten (W). The word line layer 115 may be formed by an ALD, a CVD, or other process. In some embodiments, the word line layer 115 will include a gate region that has a sidewall with a reverse dome shape, as shown in FIG. 5F.

At activity 412, a drain line layer is formed over the plurality of alternating layers 125. In some embodiments, at least a portion of the channel structure 117 formed within each of the plurality of openings are coupled to a portion of the drain line layer and a portion of the CSL 103. In some embodiments, a plurality of bit lines 118 may be deposited on top of the memory holes in the 3D NAND memory structure 100. As a result of the deposition of the plurality of bit lines 118, the channel layer 528, and the filler layer 529 may contact a drain region (e.g., N+ drain layer).

The non-abrupt shape of the reverse dome shape formed at activity 406 is distinct from the square, rectangular, or step like shape that has straight, flat, linear or planar surface shape found at the edge of conventional memory devices, which have abrupt transitions (or sharp or step-like edges) and result in uneven electric field lines and lateral charge migration, as described above. Therefore, as a result of the purposefully formed reverse dome shape, there is a reduction in the edge electric field in the 3D NAND memory structure 100 due to the non-abrupt shape of the reverse dome. In addition, in some embodiments, after activity 412, the charge trap layer 524 is thinner between the memory cells (e.g., between the word line layers 115 and adjacent to the inter-word line dielectric layers 116), such that when a voltage is applied to the gate of the word line layer 115, the charge is trapped at the portion of the charge trap layer 524 adjacent to the word line layer 115, and the charge not migrate vertically towards the portions of the charge trap layer 524 that are adjacent to the inter-word line dielectric layers 116. In other words, because the charge trap layer 524 is thinner when it is adjacent to the inter-word line dielectric layers 116, charge migration is limited, because the resistance to the charge flow from one region of the charge trap layer 524 to the next is strengthened as a result of the small cross sectional area of the charge trap layer 524 adjacent to the inter-word line dielectric layers 116.

### First Additional 3D NAND Device Formation and Structure Sequence

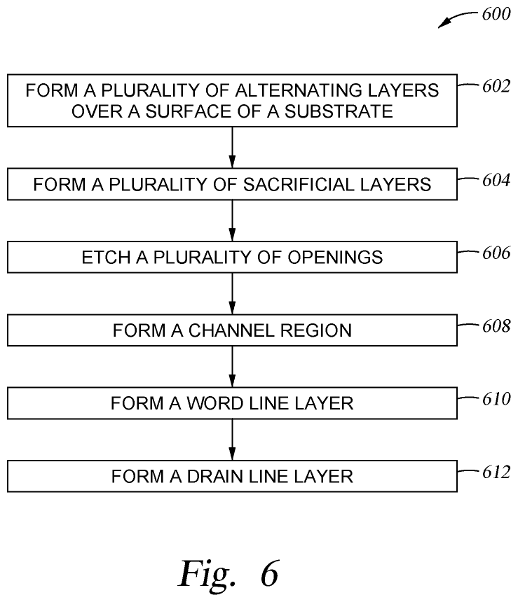

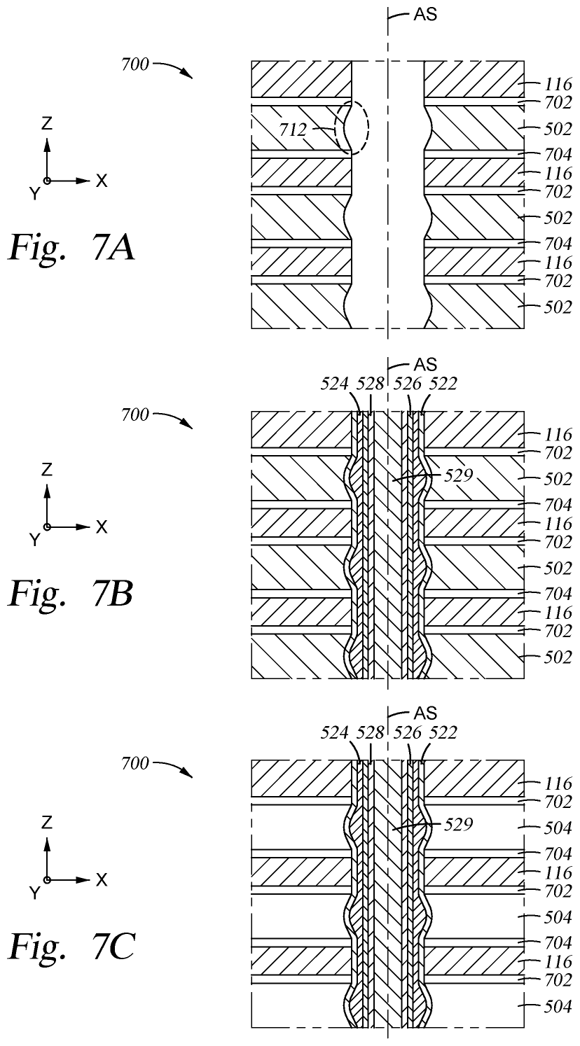

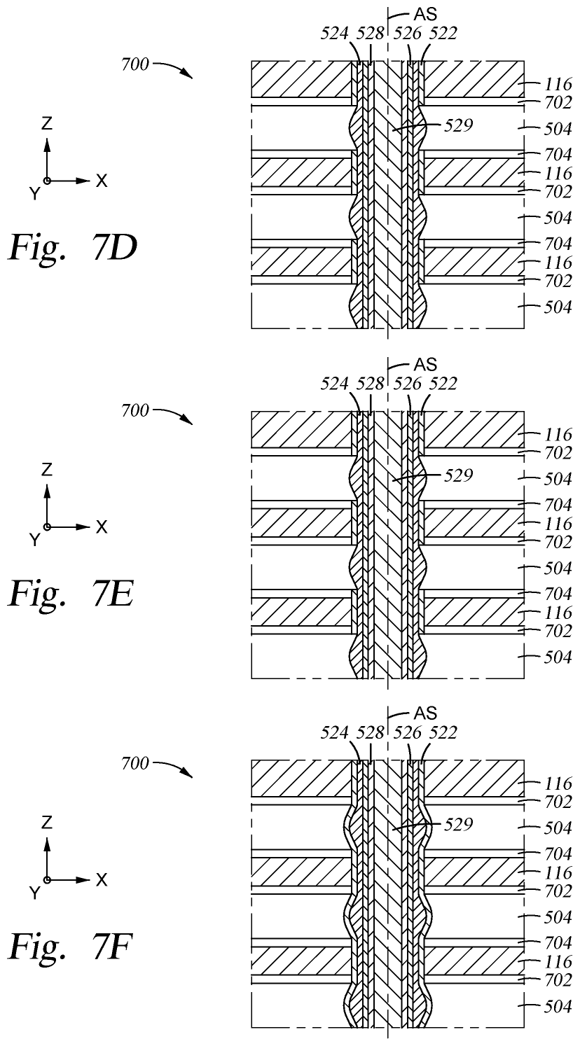

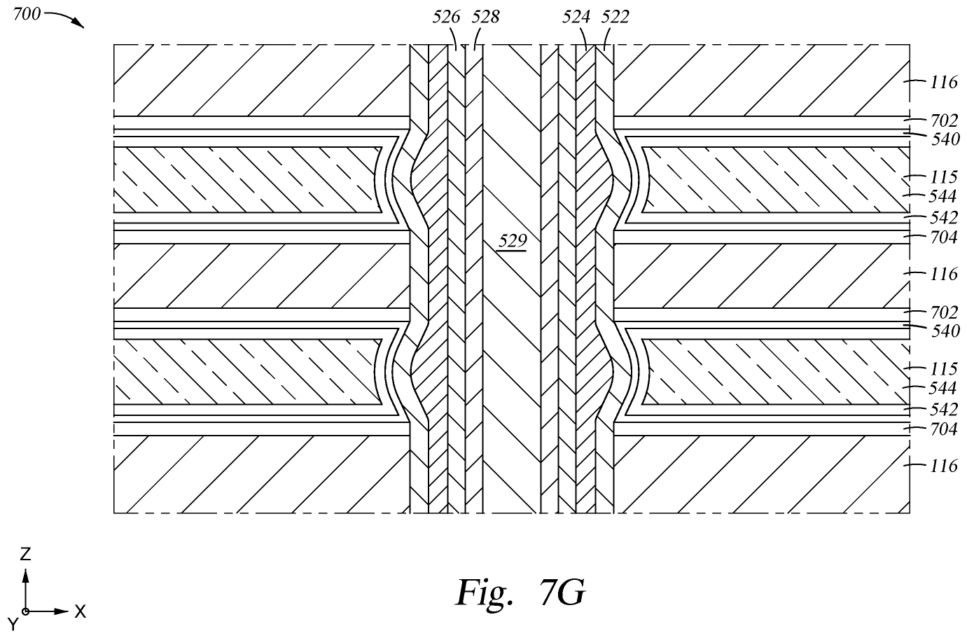

FIG. 6 illustrates a method 600 for use in the manufacturing of a memory cell gate stack portion of a semiconductor device, such as forming a portion 700 of the 3D NAND memory structure 100, according to one or more of the embodiments described herein. FIGS. 7A, 7B, 7C, 7D, 7E, 7F, and 7G illustrate schematic side cross-sectional views of portions (e.g., 700) of the 3D NAND memory structure 100 during one or more of the activities illustrated in FIG. 6, according to one or more of the embodiments described herein. Therefore, FIG. 6 and FIGS. 7A, 7B, 7C, 7D, 7E, 7F, and 7G are herein described together for clarity. It is assumed that the mold is previously deposited and that memory holes are opened by high aspect ratio etching. The portion 500 of the 3D NAND memory structure 100 may be symmetrical across the axis of symmetry (AS).

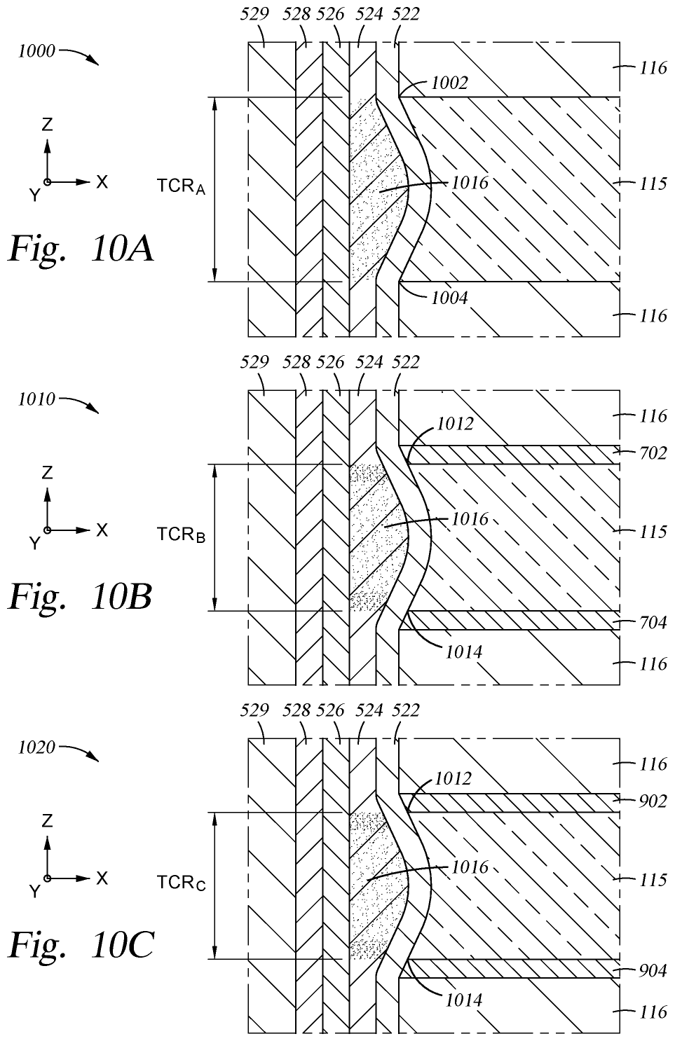

The method 600 begins at activity 602 and activity 604, where a plurality of alternating layers 125 are formed over a surface of a substrate 101. In some embodiments, forming the plurality of alternating layers 125 includes forming a plurality of dummy nitride layers 502, a plurality of inter-word line dielectric layers 116, and a plurality of sacrificial layers 702, 704 that are sequentially stacked in a first direction over a CSL 103 that is disposed over the surface of the substrate 101. In some embodiments, each of the plurality of sacrificial layers 702, 704 are interleaved between adjacently positioned dummy nitride layers 502 and inter-word line dielectric layers 116. In some embodiments, the sacrificial layers 702, 704 may be a silicon oxide layer that is doped, or any other doped material. In some embodiments, the dielectric layers 116 may be doped with material that is fluorinated or hydrogenated. The sacrificial layers 702, 704 are configured to offset the edge of the word line layer 115, in order to mitigate the electric field formed at the outside edges of the gate region (e.g., gate region 1016 in FIG. 10B) and near the corners of the word line layer (e.g., 1012, 1014 in FIG. 10B). In some embodiments, word line layer 115 may be smaller than a conventional word line layer as a result of the addition of the sacrificial layers 702 and 704, thereby creating the offset which mitigates the corner effect. In some embodiments, activities 602 and 604 may be performed simultaneously. In some embodiments, the sacrificial layers 702, 704 may be referred to as shielding layers, or as offsetting layers.

At activity 606, a plurality of openings (e.g., memory holes) extending in the first direction from the CSL 103 and through the plurality of alternating layers 125 are etched, as shown in FIG. 7A. The memory holes may be etched using a high aspect ratio etching process. Further, the memory holes extend from a CSL 103 through a plurality of alternating layers 125 perpendicular (e.g., −Z-direction) to a major surface of the substrate 101. In some embodiments, a recess (e.g., recess 712) may optionally be selectively formed in a surface of each of the plurality of dummy nitride layers 502 that are exposed within each of the formed memory holes 501, as discussed above with respect to activity 406. The selectively formed recesses may each have a reverse dome shape (e.g., recesses 712 in FIG. 7A) in order to reduce the electric field formed at the edges of the gate regions and near the edges of the word line layer 115.

At activity 608, a channel structure 117 (e.g., channel region) may be formed within the memory holes. The process of forming the channel structure 117 includes depositing an ONO layer stack over the surface of each of the memory holes in a portion 700 of the 3D NAND memory structure 100 by use of an atomic layer deposition (ALD) or chemical vapor deposition (CVD) process, as shown in FIG. 7B. Depositing the ONO layer stack includes forming a first dielectric layer (e.g., first oxide layer 522) which conforms to the sidewall of the dummy nitride layer 502. The process of depositing the first oxide layer 522 may include, for example, depositing a layer (e.g., a continuous layer) of aluminum oxide (Al₂O₃ or similar) and or silicon oxide (SiOₓ) on sides that define the plurality of openings formed in the plurality of alternating layers 125 and along the CSL 103 and/or ESL 102 at the bottom of the memory holes. The first oxide layer(s) 522 are forming so-called barrier oxide and high-k layer of the memory cell.

The process of depositing the ONO layer stack also includes depositing a first silicon nitride layer (e.g., charge trap layer 524) on the first oxide layer 522 by use of an atomic layer deposition (ALD) or chemical vapor deposition (CVD) process, as shown in FIG. 7E. The charge trap layer 524 may include a layer of trap-silicon nitride (Si₃N₄), or even a polycrystalline silicon (poly-Si) layer (floating gate NAND cell architecture).

The process of depositing the ONO layer stack may also include forming a second dielectric layer (e.g., second oxide layer 526) over the charge trap layer 524 by use of an atomic layer deposition (ALD) or chemical vapor deposition (CVD) process, as shown in FIG. 7B. The second oxide layer 526 may include a layer of silicon oxide (SiOₓ) or band-gap engineered combination of the SiO₂/SiN/SiO₂. The second oxide layer 526, or the combination of band-gap engineered layers, can be used to form a tunneling oxide region of the device. The first oxide layer 522, the charge trap layer 524, and the second oxide layer 526 altogether form the simplified ONO layer stack.

At activity 608, a channel region is formed over the first oxide layer 522, the charge trap layer 524, and the second oxide layer 526. The process of forming the channel structure 117 includes depositing a channel layer 528 in the plurality of openings over the second oxide layer 526, by use of an atomic layer deposition (ALD) or chemical vapor deposition (CVD) process, as shown in FIG. 7B. In one example, the channel layer 528 may include a polysilicon layer. In one example, the channel layer 528 may be an amorphous indium zinc oxide (IZO) containing layer. In another example, the channel layer 528 may be a multi-layer channel that includes two or more layers that are formed of different materials. For example, a first part of the channel layer may be indium zinc oxide (IZO), and a second part of the channel layer may be an amorphous indium gallium zinc oxide (IGZO) containing part.

In some embodiments of activity 608, a filler layer 529 is deposited in the memory holes in a portion of the 3D NAND memory structure 100 on the channel layer 528. For example, the filler layer material may be silicon dioxide (SiO₂), aluminum oxide (Al₂O₃), or silicon nitride (Si₃N₄). In some embodiments, the deposition of the filler layer 529 may fill the remainder of the memory hole in the 3D NAND memory structure 100. The filler layer 529, such as an oxide layer, can be deposited using any suitable deposition processes and/or apparatus. For example, physical vapor deposition (PVD), atomic layer deposition (ALD) or chemical vapor deposition (CVD) may be used to deposit the channel layer 528 and second channel layer, the ONO layer stack, and the filler layer 529. Alternatively or additionally, a stand-alone apparatus or a cluster tool can be used to perform an atomic layer deposition (ALD) process. Exemplary apparatus that can be configured for performing the above process include, for example, the OLYMPIA line of ALD apparatus, available from Applied Materials, Inc.

FIG. 7C illustrates a portion 700 of the memory structure after removing the dummy nitride layer 502 and a portion of the first oxide layer 522 is removed by use of an etching process. FIG. 7D illustrates a portion 700 of the memory structure after removing a portion of first oxide layer 522 over the gate region of each memory cell, so that the charge trap layer 524 can be grown in subsequent steps. The removal of the first oxide layer 522 may be accomplished by etching, which exposes the charge trap layer 524. FIG. 7E illustrates a portion 700 of the memory structure after a charge trap layer 524 is grown on the first oxide layer 522. FIG. 7F illustrates a portion 700 of the memory structure after a second oxide layer 526 is grown over the charge trap layer 524.

At activity 610, a word line layer 115 is formed in place of the removed dummy nitride layer 504 and over the ONO stack, as illustrated in FIG. 7G. After activity 610, a node separation process is performed in the 3D NAND memory structure 100, also as illustrated in FIG. 7G. The word line layer 115 may include three layers, a first layer 540 which is aluminum oxide (Al₂O₃), a second layer 542 which is titanium nitride (TiN), and a third layer 544 which may be molybdenum (Mo) or Tungsten (W). The word line layer 115 may be formed by an ALD, a CVD, or other process. In FIGS. 7A, 7B, 7C, 7D, 7E, and 7F, the first, second, and third layers of the word line layer 115 are not shown for clarity of discussion.

At activity 612, a drain line layer is formed over the plurality of alternating layers 125. In some embodiments, at least a portion of the channel structure 117 formed within each of the plurality of openings are coupled to a portion of the drain line layer and a portion of the CSL 103. In some embodiments, a plurality of bit lines 118 may be deposited on top of the memory holes in the 3D NAND memory structure 100. FIG. 7F also illustrates a portion 700 of the 3D NAND memory structure 100 after a selective oxidation is performed to form a bit line 118 gate oxide in the 3D NAND memory structure 100. As a result of the deposition of the plurality of bit lines 118, the channel layer 528, and the filler layer 529 may contact a drain region (e.g., N+ drain layer).

### Second Additional 3D NAND Device Formation and Structure Sequence

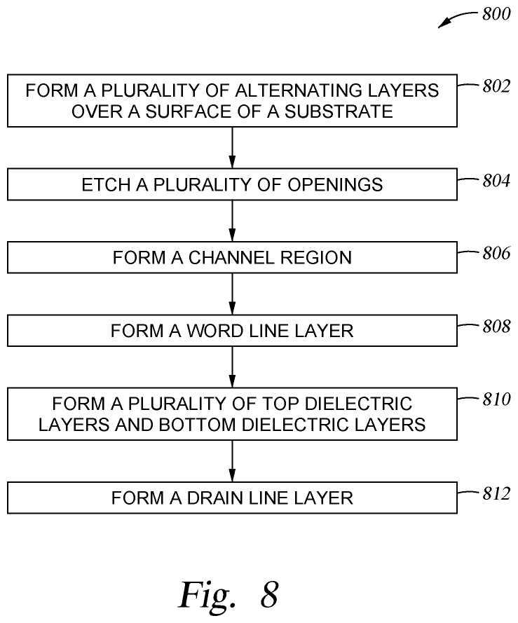

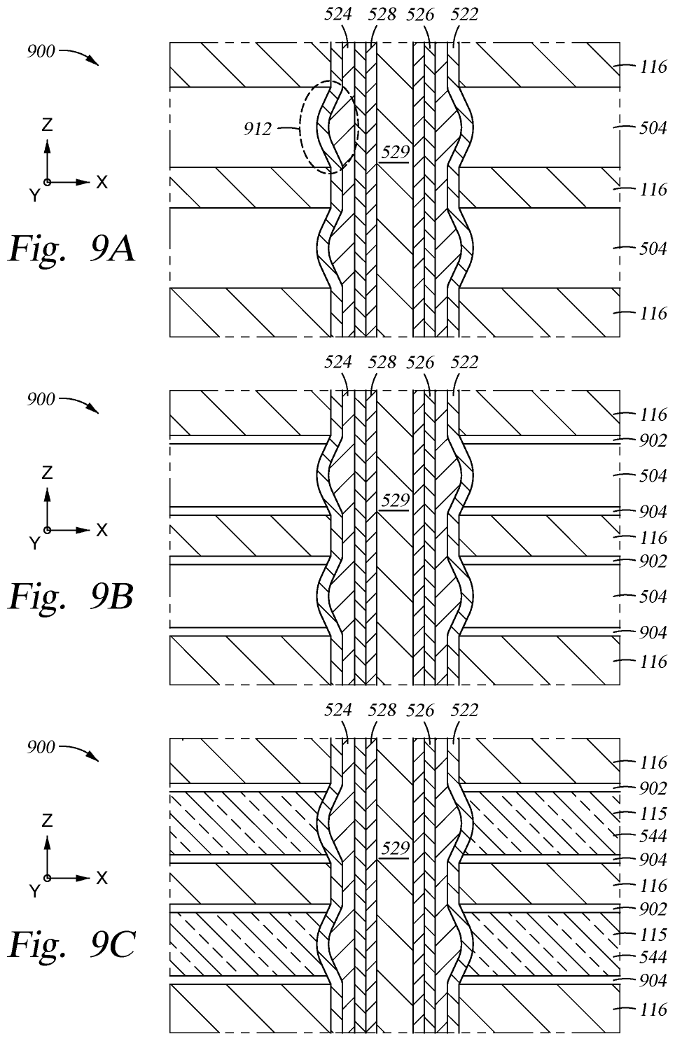

FIG. 8 illustrates a method 800 for use in the manufacturing of a memory cell gate stack portion of a semiconductor device, such as forming a portion 700 of the 3D NAND memory structure 100, according to one or more of the embodiments described herein. FIGS. 9A, 9B, and 9C illustrate schematic side cross-sectional views of portions (e.g., 900) of the 3D NAND memory structure 100 during one or more of the activities illustrated in FIG. 8, according to one or more of the embodiments described herein. Therefore, FIG. 8 and FIGS. 9A, 9B, and 9C are herein described together for clarity. It is assumed that the plurality of alternating layers 125 were previously deposited and that memory holes are opened by high aspect ratio etching. The portion 500 of the 3D NAND memory structure 100 may be symmetrical across the axis of symmetry (AS).

The method 800 begins at activity 802, where a plurality of alternating layers 125 are formed over a surface of a substrate 101. In some embodiments, forming the plurality of alternating layers 125 may include forming a plurality of dummy nitride layers 502 and a plurality of inter-word line dielectric layers 116 that are sequentially stacked in a first direction over a CSL 103 that is disposed over the surface of the substrate 101.

At activity 804, a plurality of openings (e.g., memory holes) extending in the first direction from the CSL 103 and through the plurality of alternating layers 125 are etched. The memory holes 501 may be etched using a high aspect ratio etching process. Further, the memory holes extend from a CSL 103 (FIG. 1) through a plurality of alternating layers 125 perpendicular (e.g., −Z-direction) to a major surface of the substrate 101. In some embodiments, a recess (e.g., recess 912) may optionally be selectively formed in a surface of each of the plurality of dummy nitride layers 502 that are exposed within each of the formed memory holes 501, as discussed above with respect to activity 406. The selectively formed recesses may each have a reverse dome shape (e.g., recesses 912 in FIG. 9A) in order to reduce the electric field formed at the edges of the gate regions and near the edges of the word line layer 115.

At activity 806, a channel structure 117 is formed within the memory holes 501. The process of forming the channel structure 117 includes depositing an ONO layer stack over the surface of each of the memory holes 501 in a portion 900 of the 3D NAND memory structure 100 by use of an atomic layer deposition (ALD) or chemical vapor deposition (CVD) process. Depositing the ONO layer stack includes forming a first dielectric layer (e.g., first oxide layer 522) which conforms to the shape of a sidewall of the dummy nitride layer 502. The process of depositing the first oxide layer 522 may include, for example, depositing a layer (e.g., a continuous layer) of aluminum oxide (Al₂O₃ or similar) and or silicon oxide (SiOₓ) on sides that define the plurality of openings formed in the plurality of alternating layers 125 and along the CSL 103 and/or ESL 102 at the bottom of the memory holes. The first oxide layer(s) 522 are forming so-called barrier oxide and high-k layer of the memory cell.

The process of depositing the ONO layer stack also includes depositing a first silicon nitride layer (e.g., charge trap layer 524) on the first oxide layer 522 by use of an atomic layer deposition (ALD) or chemical vapor deposition (CVD) process. The charge trap layer 524 may include a layer of trap-silicon nitride (Si₃N₄), or even a polycrystalline silicon (poly-Si) layer (floating gate NAND cell architecture).

The process of depositing the ONO layer stack may also include forming a second dielectric layer (e.g., second oxide layer 526) over the charge trap layer 524 by use of an atomic layer deposition (ALD) or chemical vapor deposition (CVD) process. The second oxide layer 526 may include a layer of silicon oxide (SiOₓ) or band-gap engineered combination of the SiO₂/SiN/SiO₂. The second oxide layer 526, or the combination of band-gap engineered layers, can be used to form a tunneling oxide region of the device. The first oxide layer 522, the charge trap layer 524, and the second oxide layer 526 altogether are an example of a simplified ONO layer stack.

The process of forming the channel structure 117 also includes depositing a channel layer 528 in the plurality of openings over the second dielectric layer 526, by use of an atomic layer deposition (ALD) or chemical vapor deposition (CVD) process. In one example, the channel layer 528 may include a polysilicon layer. In one example, the channel layer 528 may be an amorphous indium zinc oxide (IZO) containing layer. In other examples, the channel layer 528 may be a multi-layer channel that includes two or more layers that are formed of different materials. For example, a first part of the channel layer may be indium zinc oxide (IZO), and a second part of the channel layer may be an amorphous indium gallium zinc oxide (IGZO) containing part.

In some embodiments of the channel structure 117, a filler layer 529 is deposited in the memory holes in a portion of the 3D NAND memory structure 100 on the channel layer 528. In one example, the filler layer material may be silicon dioxide (SiO₂), aluminum oxide (Al₂O₃), or silicon nitride (Si₃N₄). In some embodiments, the deposition of the filler layer 529 may fill the remainder of the memory hole in the 3D NAND memory structure 100. The filler layer 529, such as an oxide layer, can be deposited using any suitable deposition processes and/or apparatus. For example, physical vapor deposition (PVD), atomic layer deposition (ALD) or chemical vapor deposition (CVD) may be used to deposit the channel layer 528 and second channel layer, the ONO layer stack, and the filler layer 529. Alternatively or additionally, a stand-alone apparatus or a cluster tool can be used to perform an atomic layer deposition (ALD) process. Exemplary apparatus that can be configured for performing the above process include, for example, the OLYMPIA line of ALD apparatus, available from Applied Materials, Inc.

FIG. 9A illustrates a portion of the structure after depositing a barrier metal in the opening in the cells of the 3D NAND memory structure 100. At activity 808, a word line layer 115 is formed in place of the removed dummy nitride layer 504 and over the ONO stack, as shown in FIG. 9B. The word line layer 115 may include three layers, a first layer which is aluminum oxide (Al₂O₃), a second layer which is titanium nitride (TiN), and a third layer which may be molybdenum (Mo) or Tungsten (W). The word line layer 115 may be formed by an ALD, a CVD, or other process. In FIGS. 9B and 9C, the first, second, and third layers of the word line layer 115 are not shown for clarity of discussion.

At activity 810, a plurality of top shielding dielectric layers 902 each deposited on a top portion of each of the plurality of the word line layers 115, and a plurality of bottom shielding dielectric layers 904 each deposited on a bottom portion of each word line layer may be formed, as illustrated in FIG. 9B. In some embodiments, the plurality of top shielding dielectric layers 902 and the plurality of bottom shielding dielectric layers 904 are both formed in a second direction, such as at least one of the X and Y directions, which are different from a first direction, such as the Z-direction. In some embodiments, the top and bottom shielding dielectric layers may be doped. In some embodiments, the shielding dielectric layers may be doped with material that is fluorinated or hydrogenated. In some embodiments, the top shielding dielectric layer 902 and the bottom shielding dielectric layer 904 are selectively grown only horizontally, and are not grown over the gate region of the word line layers 115. The top shielding dielectric layer 902 and the bottom shielding dielectric layer 904 may be configured to offset a position of the word line layer 115, in order to reduce the electric field formed at the edges of the gate region (e.g., gate region 1026 in FIG. 10C) and near the corners of the word line layer (e.g., 1022, 1024 in FIG. 10C). In some embodiments, the shielding dielectric layers 902, 904 may be referred to as sacrificial layers, or as offsetting layers.

In some embodiments, the plurality of top shielding dielectric layers 902 and the plurality of bottom shielding dielectric layers 904 will minimize the thickness of the word line layer 115. In one method for the creation of the top and bottom shielding dielectric layers 902, 904, the following steps can be taken: anisotropic aluminum oxide (Al₂O₃) etch, and redeposition of Al₂O₃. This may result in the target thickness in the lateral direction, but may also result in a larger thickness of the Al₂O₃ in the vertical direction (stacking direction). The formation of the Al₂O₃ layer may also provide a smaller word line thickness that will offset the metal from the edge of the gate region, which will minimize the generated electric field strength at the corner of the formed flat or step shaped structure. In another method, before the initial Aluminum Oxide (AlOx) deposition, an oxygen containing surface can be functionalized so that the AlOx will preferentially grow on the horizontal surfaces (only on oxygen contain surfaces of the dielectric layers 116). As a result of the plurality of top shielding dielectric layers 902 and the plurality of bottom shielding dielectric layers 904, the word line layer 115 is offset from the corner electric field(s) originating from the gate region of the NAND device during operation, thereby attenuating the electric field and minimizing charge migration. In this example, the charge is stored in a smaller portion of the trapped charge region (TCR) of the charge trap layer 524 as a result of the sacrificial layers 902, 904, as illustrated in FIG. 10C.

At activity 812, a drain line layer is formed over the plurality of alternating layers 125. In some embodiments, at least a portion of the channel structure 117 formed within each of the plurality of openings are coupled to a portion of the drain line layer and a portion of the CSL 103. In some embodiments, a plurality of bit lines 118 may be deposited on top of the memory holes in the 3D NAND memory structure 100.

FIG. 9C illustrates a portion 900 of the 3D NAND memory structure 100 after a node separation process is performed in the 3D NAND memory structure 100.

In some embodiments, the 3D NAND memory structure 100 with an improved partial charge trap integration may include one or more of a selectively formed recess with a reverse dome shape (e.g., recesses 512, 712, 912), a plurality of sacrificial layers (e.g., sacrificial layers 702, 704), and top and bottom dielectric layers (dielectric layers 902 and 904) simultaneously.

FIGS. 10A, 10B, and 10C provide diagrams illustrating a 3D NAND memory structure 100 with an improved partial charge trap integration, according to one or more of the embodiments described herein. In FIG. 10A, the energy field will be highest at the opposing corners of the word line layer 115 (e.g. 1002, 1004 in FIG. 10A). FIG. 10A also illustrates a point at which a reverse dome shape in the dummy nitride layer 502 is formed within the stacked layer pairs 120 within the plurality of alternating layers 125 before the dummy nitride layer 502 is removed and the word line layer 115 is formed. As a result of the reverse dome shape, the electric field in the gate regions (e.g., gate region 1006) of a memory device may be modified.

In some embodiments, the reverse dome shape may form soft corners with the inter-word line dielectric layers 116, as illustrated in FIG. 10A. These soft corners are distinct from the sharp, step-like and precise corners formed by the rectangular step or flat shaped gate structure (e.g., 202) and the dielectric layer 522 in conventional structures, as described above with respect to FIG. 2. In some embodiments, the corners formed by the reverse dome shape and the inter-word line dielectric layers 116 may form an angle that is greater than 90 degrees, as illustrated in FIG. 10A.

The purposefully formed reverse dome shape causes the charge after applying a bias to be more centralized in the trapped charge region (TCR) of the charge trap layer 524, as well as a reduction in the edge electric field in the 3D NAND memory structure 100. In addition, the charge trap layer 524 is thinner between the memory cells (e.g., between the word line layers 115 and adjacent to the inter-word line dielectric layers 116), such that the charge is trapped at the portion of the charge trap layer 524 adjacent to the word line layer 115.

FIG. 10B illustrates a sacrificial layer 702, 704 (e.g., doped silicon oxide), which is configured to offset the position of the word line layer 115 in order to modify the electric field of the gate regions of a memory device. In FIG. 10B, the energy field will be highest at the opposing corners of the word line layer 115 (e.g. 1012, 1014 in FIG. 10B). Doping the sacrificial layers 702, 704 changes the etch rate, and therefore when forming the word line layer 115, the edge or position of the word line layer 115 may be offset at the location of the dome shape, as illustrated in FIG. 10B. As a result of the offset, the electric field in the gate regions (e.g., gate region 1016) of a memory device may be modified. In this example, the charge is stored in a smaller portion of the TCR of the charge trap layer 524 as a result of the sacrificial layers 702, 704, as illustrated in FIG. 10B.

FIG. 10C illustrates top dielectric layer 902 and bottom dielectric layer 904, which are configured to offset the position of the word line layer 115 in order to modify the electric field of the gate regions of a memory device. In FIG. 10C, the energy field will be highest at the opposing corners of the word line layer 115 (e.g. 1022, 1024 in FIG. 10C). As a result of the offset created by the top and bottom dielectric layers 902, 904, the electric field in the gate regions (e.g., gate region 1026) of a memory device may be modified. In this example, the charge is stored in a smaller portion of the TCR of the charge trap layer 524 as a result of the sacrificial layers 902, 904, as illustrated in FIG. 10C.

While the foregoing is directed to embodiments of the present disclosure, other and further embodiments of the disclosure may be devised without departing from the basic scope thereof, and the scope thereof is determined by the claims that follow.

We claim:

1. A three-dimensional memory device, comprising:
a plurality of alternating layers formed over a surface of a substrate, wherein the plurality of alternating layers comprise word line layers and inter-word line dielectric layers that are sequentially stacked in a first direction, wherein each of the word line layers has a gate region that has a sidewall that has a reverse dome shape;
a channel having a first end coupled to a source line, a second end coupled to a drain line, and extending in the first direction between the source line and the drain line; and
an ONO layer stack disposed between the gate regions and the channel, wherein the ONO layer stack extends in the first direction between the source line and the drain line.

2. The three-dimensional memory device of claim 1, wherein the ONO layer stack comprises a first silicon nitride layer formed within the three-dimensional memory device, and wherein the first silicon nitride layer comprises a half cylinder shape in each of the gate regions of the word line layers within the plurality of alternating layers.

3. The three-dimensional memory device of claim 2, wherein the reverse dome shape is formed on the sidewall using a recessing process that comprises:
preferentially etching a dummy nitride layer formed between the inter-word line dielectric layers before the word line layer, wherein the preferential etching of the dummy nitride layer causes a reverse dome shape to be formed in the dummy nitride layer;
depositing the ONO stack; and
forming the word line layer over the ONO stack.

4. The three-dimensional memory device of claim 2, wherein the ONO layer stack further comprises:
a first oxide layer disposed on the word line layers and inter-word line dielectric layers;
a second oxide layer disposed on the first silicon nitride layer;
a channel layer disposed on the second oxide layer; and
a filler layer disposed on the channel layer.

5. The three-dimensional memory device of claim 1, further comprising an offsetting layer disposed between the word line layer and the inter-word line dielectric layer.

6. The three-dimensional memory device of claim 5, wherein the offsetting layer is a silicon oxide layer that is doped.

7. The three-dimensional memory device of claim 5, wherein the offsetting layer is configured to offset a position of the word line layers.

8. A three-dimensional memory device, comprising:
a plurality of alternating layers formed over a surface of a substrate, wherein the plurality of alternating layers comprise word line layers and inter-word line dielectric layers that are sequentially stacked in a first direction, wherein each of the word line layers has a gate region that has a sidewall that has a reverse dome shape;
a channel having a first end coupled to a source line, a second end coupled to a drain line, and extending in the first direction between the source line and the drain line; and
an ONO layer stack disposed between the gate regions and the channel, wherein the ONO layer stack comprises a first oxide layer, a first silicon nitride layer and a second oxide layer and extends in the first direction between the source line and the drain line, and wherein:
the first oxide layer conforms to the reverse dome shape of the sidewall;
the first silicon nitride layer is disposed between the first oxide layer and the second oxide layer;
the first silicon nitride layer has a first portion that substantially fills a space formed in the gate regions between the reverse dome shape of the first oxide layer and a surface of the second oxide layer;
the first silicon nitride layer has a plurality of second portions that are disposed over each of the inter-word line dielectric layers and between gate regions; and
a thickness of the first silicon nitride layer in a first direction is less over a surface of the inter-word line dielectric layers than a thickness of the first silicon nitride layer in the first direction over the gate regions of the word line layers.

9. The three-dimensional memory device of claim 8, wherein the first silicon nitride layer comprises a half cylinder shape in each of the gate regions of the word line layers within the plurality of alternating layers.

10. The three-dimensional memory device of claim 9, wherein the reverse dome shape is formed on the sidewall using a recessing process that comprises:
preferentially etching a dummy nitride layer formed between the inter-word line dielectric layers before the word line layer, wherein the preferential etching of the dummy nitride layer causes a reverse dome shape to be formed in the dummy nitride layer;
depositing the ONO stack; and
forming the word line layer over the ONO stack.

11. The three-dimensional memory device of claim 10, wherein the ONO layer stack further comprises:
a channel layer disposed on the second oxide layer; and
a filler layer disposed on the channel layer.

12. The three-dimensional memory device of claim 8, further comprising an offsetting layer disposed between the word line layer and the inter-word line dielectric layer.

13. The three-dimensional memory device of claim 12, wherein the offsetting layer is a silicon oxide layer that is doped.

14. The three-dimensional memory device of claim 12, wherein the offsetting layer is configured to offset a position of the word line layers.

15. A method of forming a three-dimensional memory device, comprising:
forming a plurality of alternating layers over a surface of a substrate, comprising:
forming a plurality of dummy nitride layers and a plurality of inter-word line dielectric layers that are sequentially stacked in a first direction over a source line layer that is disposed over the surface of the substrate; and
etching a plurality of openings extending in the first direction from the source line layer and through the plurality of alternating layers;
selectively forming a recess in a surface of each of the plurality of dummy nitride layers that are exposed within each of the formed plurality of openings, wherein the selectively formed recesses each have reverse dome shape;
forming a channel region within the plurality of openings, comprising:
depositing an ONO layer stack over the surface of each of the plurality of openings; and
forming a channel over a surface of the ONO layer stack; and
removing the plurality of dummy nitride layers;
forming a plurality of word line layers in place of the removed plurality of dummy nitride layers and over the ONO stack, wherein the word line layers each have a gate region that has a sidewall that has a reverse dome shape; and
forming a drain line layer over the plurality of alternating layers, wherein at least a portion of the channel region formed within each of the plurality of openings are coupled to a portion of the drain line layer and a portion of the source line layer.

16. The method of claim 15, wherein the ONO layer stack extends in the first direction between the source line and the drain line, and wherein depositing the ONO layer stack over the surface of each of the plurality of openings comprises:
depositing a first oxide layer which conforms to the reverse dome shape of the sidewall;
depositing a first silicon nitride layer over the first oxide layer; wherein:
the first silicon nitride layer conforms to the reverse dome shape of the first oxide layer; and
a thickness of the first silicon nitride layer in the first direction is greater over a surface of the inter-word line dielectric layers than a thickness of the first silicon nitride layer in the first direction over the gate region of the word line layer; and
etching the first silicon nitride layer to minimize the thickness of the first silicon nitride layer over the surface of the inter-word line dielectric layers.

17. The method of claim 16, wherein the first silicon nitride layer comprises a half cylinder shape in each of the gate regions of the word line layers within the plurality of alternating layers.

18. The method of claim 16, wherein the thickness of the first silicon nitride layer in a first direction is less over the surface of the inter-word line dielectric layers than the thickness of the first silicon nitride layer in the first direction over the gate regions of the word line layers.

19. The method of claim 16, wherein depositing the ONO layer stack over the surface of each of the plurality of openings comprises:
depositing a second oxide layer over the first silicon nitride layer;
depositing a channel layer disposed on the second oxide layer; and
depositing a filler layer disposed on the channel layer.

20. The method of claim 16, further comprising forming a plurality of offsetting layers disposed between the word line layers and the inter-word line dielectric layers.
